(19) United States
(12) Patent Application Publication
(10) Pub. No.: US 2017/0164504 A1
(43) Pub. Date: Jun. 8, 2017

(54) Server rack, server, as well as assembly having a server rack and a server

(71) Applicant: FUJITSU LIMITED, Kawasaki-shi (JP)

(72) Inventor: Johannes Blume, Brakel (DE)

(73) Assignee: FUJITSU LIMITED, Kawasaki-shi (JP)

(21) Appl. No.: 15/364,791

(22) Filed: Nov. 30, 2016

(30) Foreign Application Priority Data
Dec. 2, 2015 (DE) 102015120944.6

(51) Int. Cl. H05K 7/14; H05K 7/20

(52) U.S. Cl. CPC H05K 7/1491; H05K 7/1492; H05K 7/1487; H05K 7/20781; H05K 7/20772; H05K 7/20272; H05K 7/20263

(57) ABSTRACT

A server rack having a width, a height and depth of specified dimensions is provided. The server rack has a front side, a rear side and a reception region in the inside for receiving a plurality of servers. The depth (T1) of the server rack is dimensioned such that in addition to the reception region additional regions are provided both toward the front side and the rear side so that cabling of a plurality of servers received in the server rack can be received in the additional regions both on the front side and the rear side.

The invention relates to a server rack, comprising a width, height and depth of specified dimensions as well as a front side, a rear side and a reception region in the inside for receiving a plurality of servers.

Furthermore, the invention relates to a server for being received and operated in a server rack, comprising a housing with a width, height and depth of specified dimensions, a front side and a rear side as well as appropriate components for operating the server, which are received in the housing.

Conventional server racks are configured for reception of a plurality of servers. Here, the configuration of conventional server racks as well as conventional servers follows a relatively rigid operating concept. The servers are generally received in the server rack in such a way that they are accessible from a front side of the server rack for maintenance purposes. For example, a door at the front side of the server rack can be opened to obtain access to the individual servers. For example, this may be needed to administer drive plugins or other components on a server.

In a conventional configuration, all servers, with their rear-sided connections, are located in the server rack in such a way that all cabling of the server is to be done at the rear side of the server rack. On the one hand, such cabling may provide the connection of the servers to an external supply voltage and, on the other hand, provide a connection of the servers to external communication structures and/or an interconnection of the servers. That means that the entire cabling of all servers received in a server rack is conventionally configured on the rear side. Such a rigidly-specified operating concept of server racks and corresponding servers comes with the disadvantage that it is relatively inflexible in terms of the configuration and arrangement of servers received in the server rack.

It is an object of the invention to provide a server rack as well as a server of the above-mentioned type, which follow a more flexible operating concept.

In a first aspect, this object is achieved by a server rack of the above-mentioned type in that the depth of the server rack is dimensioned such that, in addition to the reception region, regions are created both toward the front side and the rear side so that cabling of a plurality of servers received in the server rack can be received in the additional regions both at the front side and at the rear side.

Compared to a conventional server rack, such a server rack provides the advantage that sufficient space for cabling of servers received in the server rack is configured both at the front side and at the rear side. In this way, the server rack of the type described herein is developed further, compared to conventional server racks, in that a further region is configured at the front side of the server rack, in which cabling can be accommodated just as well, in addition to a region at the rear side of the server rack that is created for cabling of servers.

A server rack of the type described herein thus provides the advantage over conventional rack solutions that a more convenient configuration and handling is possible in terms of cabling of servers received in the server rack. The server rack of the type described herein thus follows a more flexible operating concept, according to which cabling can be configured both at the front side and at the rear side of the server rack.

The additional regions at the front side as well as at the rear side of the server rack are designed in terms of their respective depth in such a way that sufficient space for cabling is created. Here, the term “cabling” means the cabling of a plurality of servers received in the server rack, which has a higher space requirement compared to the space available at the front side in conventional server racks. Thus, one decisive aspect of a server rack of the type provided herein is that a region at the front side is configured to be larger or deeper than a conventional region at the front side of conventional server racks. In particular, conventional server racks have different depths in the regions at the front side and at the rear side. Advantageously, the server rack of the type described herein can be configured such that both regions, i.e. the region at the front side as well as the region at the rear side, have almost the same dimensions. This way, sufficient space for a cabling of a plurality of servers received in the server rack is created both at the front side and at the rear side.

In such a configuration, servers are received in a receiving region inside the server rack, wherein the receiving region is configured between the additional region at the front side and the additional region at the rear side in the direction of a depth extension of the server rack. Servers received in the reception region in the server rack can be cabled both toward the front side and toward the rear side. This way, the server rack of the type explained herein is significantly more flexible than conventional rack solutions.

According to one embodiment of the server rack, the additional regions at the front side and the rear side, advantageously extend in each case over the entire front side and the entire rear side, respectively. In this way, a volume extending over the entire width as well as height of the server rack and having a specified depth, which corresponds to the depth of the respective region, is available for accommodating and receiving cabling of the servers received in the server rack.

Advantageously, in a cover region and/or in a bottom region of the server rack, i.e. on a cover wall or on a bottom wall, cable through-openings may be configured in the region of the front side and the rear side of the server rack, respectively. This provides the advantage that cabling can also be guided outward out of the server rack both at the front side and at the rear side. Even in this regard, the server rack represents a more flexible handling, in particular for the interconnection with further server racks.

According to one embodiment of the server rack, a power supply manifold (i.e. multi-distributer) for the connection of a plurality of servers received in the server rack to a power supply is configured in the additional regions both at the front side and at the rear side. Advantageously, the power supply manifold extends over a height across which the servers can be received in the server rack. This means that advantageously a corresponding connection of the power supply manifold is arranged at or in the region of a mounting space for a server in the server rack. For example, the power supply manifold can be arranged as a vertical distributer bar across the entire height of the server rack. Advantageously, the power supply manifold is arranged in a peripheral region at the front side or the rear side so that access to servers received in the server rack is not impeded or only slightly impeded. A connection of the servers received in the server rack to the power supply manifold is advantageously effected via electrical connection lines and corresponding plug connectors that connect a server to the power supply manifold.

Due to the configuration of the server rack with in each case one power supply manifold both at the front side and at the rear side, the server rack is flexibly configured and orientation-independent in terms of a connection of the servers to a power supply to the greatest possible extent.

According to one embodiment of the server rack, a coolant manifold (i.e. multi-distributer) for the connection of a plurality of servers received in the server rack to one or multiple coolant circuits is in each case configured in the additional regions at the front side and at the rear side. Advantageously, the coolant manifold, similar to the above explanations regarding the power supply manifold, extends over a height across which the servers can be received in the server rack. This means that advantageously a connection of the coolant manifold is arranged at or in the region of an installation space for a server in the server rack. Advantageously, the coolant manifold is configured in a peripheral region at the front side or the rear side of the server rack in order to not impede access or only slightly impede access to the servers. Advantageously, connection of the servers to the coolant manifold is effected via coolant hoses and corresponding hose connectors.

Advantageously, the coolant manifold comprises a cooling path and a heat path. This means that the coolant manifold distributes a low-temperature coolant in the direction of the servers via the cooling path, and receives coolant heated by the waste heat of the servers from the servers via the heat path. The heated coolant can be transported via a coolant circuit to a heat exchanger, by means of which the waste heat can be dissipated to the surroundings. A corresponding heat exchanger is arranged in a predetermined region of the server rack, preferably in a cover region. It is also conceivable that the heat exchanger dissipates the waste heat to a secondary circuit by means of another heat exchanger. For example, the secondary circuit can be connected to a district heating network or a heating system for heating a computing center, and so on. Various options are conceivable in this regard.

Due to the configuration of two coolant manifolds at the front side and the rear side of the server rack respectively, said server rack has a flexible configuration that is orientation-independent to the greatest possible extent with respect to the connection options of servers to a coolant circuit in the server rack. Compared to conventional rack solutions, a significantly more flexible handling of the servers in terms of cooling can be achieved by means of a server rack of the type described herein. The server rack also allows for cooling of servers both at the front side and at the rear side.

In another aspect, the above object is achieved by a server of the described type in that the server comprises one or multiple connections for the connection of the server to external operating components both at the front side and at the rear side.

Compared to conventional servers, the server of the type described herein thus provides a novel server concept. This concept comprises connection options both at the front side and at the rear side. Thus, the novel server described herein is connectable to external operating components from both sides. In this way, the server is significantly more flexible in its handling than known server concepts.

Advantageously, the connections comprises one or multiple electric supply connections for the connection of the server to an external power supply and/or one or multiple electric signal line connections for connecting the server to an external communication structure.

According to one embodiment, the server comprises at least two voltage supply units for the generation of one or multiple operating voltages from a supply voltage of an external power supply, wherein one voltage supply unit is arranged in the region of the front side of the server and connected to the electric supply connections at the front side, and wherein one voltage supply unit is arranged in the region of the rear side of the server and connected to the electric supply connections at the rear side. In this way, internal components of the server, e.g. storage drives, hard drives, system boards, expansion components and so on, can be supplied with corresponding operating voltages or operating currents via different voltage supply units. Operating components arranged in the front part of the server toward the front side can be connected to an external power supply via the respective front-side voltage supply unit. On the other hand, components arranged in the rear-sided region of the server toward the rear side can be connected to an external power supply via the voltage supply unit arranged at the rear side. In this way, the server of the type described herein comprises a more flexible configuration compared to conventional server concepts.

According to one embodiment of the server, the connections include coolant connections for the connection of the server to one or multiple coolant circuits. In this way, the coolant connections are arranged both at the front side and at the rear side of the server, so that the server can be connected to one or multiple coolant circuits from both sides. According to one embodiment, the server comprises a pump for the generation of a coolant current in a connected coolant circuit. Alternatively or in addition, the provision of an external pump system for the generation of a coolant current in the coolant circuit is conceivable. The external pump system may be configured in a server rack of the above-described type, for example.

All aspects, features and properties of the server described herein provide the advantage, per se or in combination, that components can be arranged within the server in a relatively flexible manner without relying on exclusive connection options at a rear side of the server—as in conventional solutions. That means that even a significantly higher power density in the server can be achieved due to the progressive development of servers. In particular by means of a cooling of the server by one or multiple coolant circuits, to which the server can be connected both from the front side and from the rear side, it is possible to completely or almost completely dispense with an air cooling of the server by mounted vents. Due to this fact, construction space is saved in the server, in which additional power components of the server can be configured. A greater component density in the server as well as the fact that the server has connections of the above-described type both at the front side and at the rear side, provide the synergetic effect that the server operates with a significantly higher performance than conventional server concepts.

Advantageously, the above-described aspects of a server rack as well as of a server are applied in an assembly having a corresponding server rack of the described type and at least one server of the described type, the server being received in the server rack. In such an assembly, the server rack as well as the server interact in a synergetic fashion. The server rack allows cabling or connection of the server to external operating components both at the front side and at the rear side of the server rack. In particular, the server is connectable to an external power supply and to one or multiple coolant circuits both at the front side and at the rear side. As described, the server per se is configured to be connected to external operating components via corresponding connections both at the front side and at the rear side. In this way, a plurality of servers of this type can be received in the server rack in a convenient and flexible manner. A corresponding cabling of the plurality of servers, which occupy a considerable construction space, can be accommodated both at the front side and at the rear side of the server rack.

Thus, the advantage of such an assembly is that very high-performant servers can be configured in a server rack, wherein the cabling of the servers is guided both on the front side and on the rear side of the server rack. In this way, it is no longer required to re-route cabling of a server from a front-side to a rear side of the server rack, which would significantly limit the available construction space and would be very cumbersome. Such disadvantages, as present in conventional server rack solutions, can be avoided in an advantageous manner by the server rack described herein.

Further advantageous embodiment and aspects are disclosed in the sub-claims.

Further advantageous aspects of an illustrated server rack as well as of a described server will hereinafter be described in greater details using multiple figures.

The figures show in:

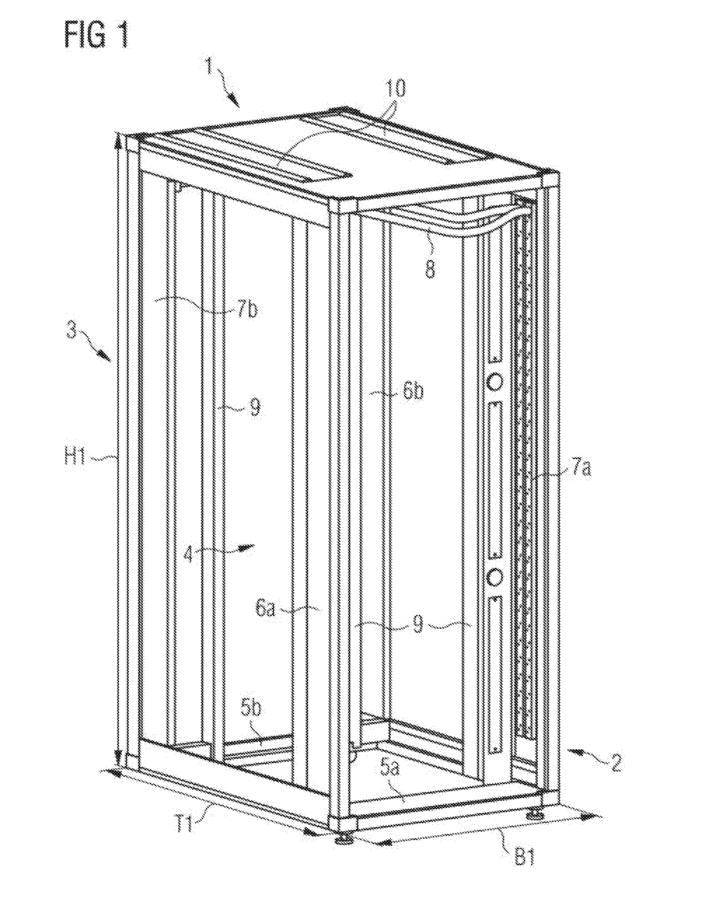

FIG. 1 a perspective illustration of an embodiment of a server rack according to the invention,

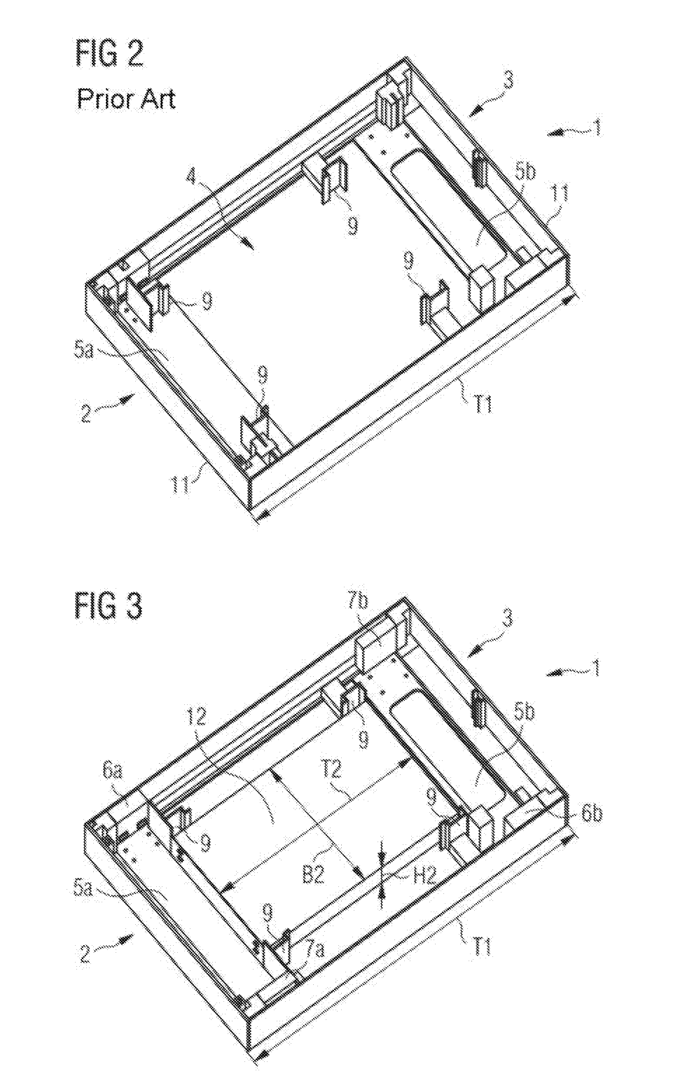

FIG. 2 a perspective illustration of a sectional view through a server rack according to the prior art,

FIG. 3 a perspective illustration of a sectional view of an assembly having a server rack and a server received in the rack according to an embodiment of the invention, and

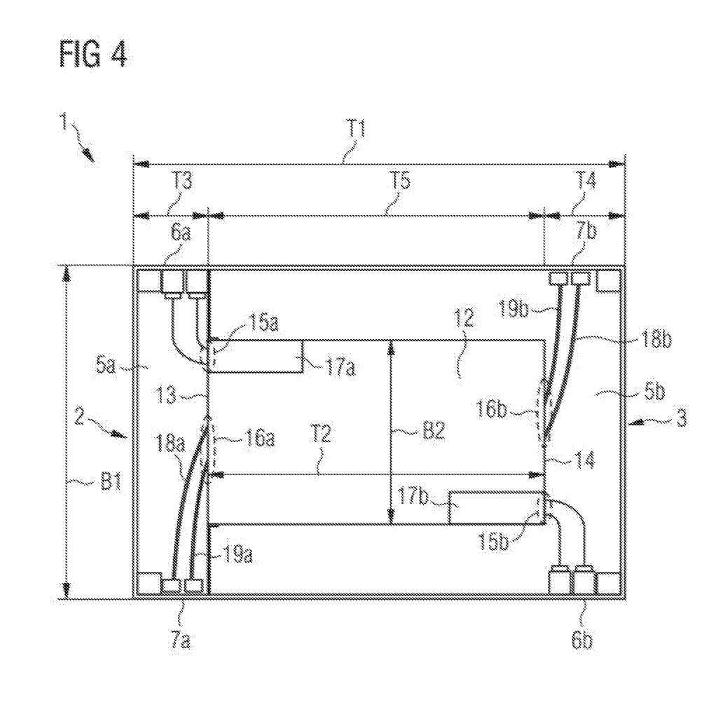

FIG. 4 a schematic illustration of a sectional view of an assembly having a server rack and a server received in the rack according to an embodiment of the invention with additional details.

FIG. 1 shows a perspective illustration of an embodiment of a server rack 1 of the above described type. The server rack 1 is configured as a server cabinet having a support frame structure and has a width B1, a height H1 as well as a depth T1 of specified dimensions. Furthermore, the server rack 1 comprises a front side 2 as well as a rear side 3. The front side 2 and/or the rear side 3 may allow access to the inside of the server rack 1 via cover panels or door elements. However, such elements are not shown for the illustration of further aspects of the server rack 1 in FIG. 1.

The server rack 1 according to FIG. 1 comprises an inner reception region 4, which is defined in its dimensions by support profiles 9. The server rack 1 comprises a total of four support profiles 9, which extend in a vertical direction along the height H1 in the server rack 1 and serve for the receiving and mounting of servers. In this way, a plurality of servers can be received in the server rack 1, wherein the receiving region 4 occupies an inner sub-volume of the server rack 1.

According to the embodiment in FIG. 1, the server rack 1 is designed in such a way that the depth T1 of the server rack 1 is dimensioned such that additional regions 5a and 5b are created both toward the front side 2 and toward the rear side 3 in addition to the reception region 4. These additional regions 5a and 5b serve for the reception of a cabling of a plurality of servers received in the server rack 1 both at the front side 2 and at the rear side 3. That means that the server rack 1 is flexibly configured for the reception of cabling both at the rear side 3 (as is possible in convention server racks 1) and at the front side 2. Thus, the server rack 1 advantageously enables the flexible accommodation of servers, wherein it is conceivable, for example, to accommodate servers with connections in the rear wall region thereof in the server rack 1 in such a way that the rear wall connections of the servers are oriented either toward the rear side 4 or toward the front side 2 of the server rack 1. This may be advantageous depending on the specific case of use in terms of cabling servers amongst one another.

However, it is also conceivable to receive servers in the server rack 1, wherein the servers per se comprise connections for the connection of the servers to external operating components both at a front side and at a rear side. Such a constellation will be described in greater detail below.

The server rack 1 according to the embodiment in FIG. 1 comprises in each case one power supply manifold 6a and 6b both in region 5a at the front side 2 and in region 5b at the rear side 3. The two power supply manifolds 6a and 6b are arranged in a peripheral region at the front side 2 and the rear side 3 in the server rack 1, respectively. The power supply manifolds 6a and 6b are designed as vertical distributer bars and advantageously extend over a height of the server rack 1 across which the servers can be received in the server rack 1. This means that an electric connection option of a corresponding server is present by means of the power supply manifolds 6a and 6b ideally at or in the region of all mounting positions specified by the support profiles 9 in the server rack 1. Thus, a server received in a server rack 1 can be connected with an external power supply by means of the power supply manifolds 6a and 6b toward the front side 2 and/or toward the rear side 3.

In addition, the server rack 1 comprises in each case one coolant manifold 7a and 7b both at the front side 2 and at the rear side 3. The two coolant distributers 7a and 7b are also arranged in a peripheral region at the front side 2 and the rear side 3, respectively. According to the embodiment of the server rack in FIG. 1, the two coolant manifolds 7a and 7b are arranged opposite the power supply manifolds 6a and 6b. Via coolant lines 8, discernable in an upper region at the front side 2 in FIG. 1, the coolant manifolds 7a and 7b are connected to one or multiple heat exchangers (not illustrated). The two coolant manifolds 7a and 7b each comprise a cooling path and a heat path and serve for the connection of servers received in the server rack 1 to a coolant circuit. In particular, this means that a server received in the server rack 1 is connected to one or both coolant manifolds 7a and 7b in such a way that one or multiple coolant circuits for circulating coolant for dissipation of waste heat from the server via a heat exchanger toward the surroundings of the server rack 1 is achieved between the server and the coolant manifolds 7a and 7b. Even with respect to the coolant manifolds 7a and 7b, the server rack 1 according to FIG. 1 comprises a flexible connection option for the server.

Cover openings 10 are configured in the cover region of the server rack 1. The cover openings 10 can be configured as vent openings for the dissipation of waste heat and/or openings for cable through-openings for guiding cabling out from the server rack 1. In an embodiment not shown here, it is also conceivable to provide the cover openings 10 in particular also in the region of the front side 2 and the rear side 3, respectively, so that cabling from the additional regions 5a and 5b can be guided out from server rack 1 directly via the cover openings 10. The same may also be provided in a bottom region of the server rack 1.

FIG. 2 shows a perspective illustration of a sectional view through an embodiment of a server rack 1 according to the prior art. This embodiment is explained in order to explain essential differences of a server rack 1 of the present developed type compared to server rack concepts known from the prior art. The server rack 1 of FIG. 2 comprises a front side 2 as well as a rear side 3, which are formed by corresponding cover panels 11.

An inner receiving region 4 for receiving servers is configured inside of the server rack 1, the region formed by four rectangularly arranged vertical support profiles 9. As also described in the context of the embodiment according to the invention of a server rack 1 of FIG. 1, the support profiles 9 in the server rack 1 according to FIG. 2 serve for the reception of servers in the server rack 1.

According to FIG. 2, the server rack 1 comprises a region 5a at the front side 2 thereof, in which access to the servers (not shown) arranged at the support profiles 9 after a removal of the cover panel(s) 11 is possible. The region 5a has a comparatively small depth due to the configuration of the rack server 1 with support profiles 9 directly located behind the cover panel(s) 11. In particular, region 5a has a significantly smaller depth than region 5b, which is configured at the rear side 3 of the server rack 1 of FIG. 2. In this way, reception and accommodation of cables of a plurality of servers received in the server rack 1 of FIG. 2 can merely be realized above region 5b at the rear side 3 of the server rack. In the front side 5a of the server rack 1 of FIG. 2, such cabling of a plurality of servers cannot be received, since the mounting space available here is not sufficient. In particular for a combined cabling of electric signal lines or electric supply lines and additional coolant lines, as explained in the context of a server rack 1 of FIG. 1, region 5a in the server rack 1 of FIG. 2 does not provide sufficient space. This comes with the disadvantage that servers received in the server rack 1 of FIG. 2 can exclusively be cabled via the rear side 3. Even if servers are received with a front-sided connection option in the server rack 1 of FIG. 2, a cabling of the server would have been guided via peripheral regions in the server rack 1 to the rear side 3. However, this is also very cumbersome due to the conventionally narrow front region 5a.

The sectional view of an embodiment of a server rack 1 illustrated in FIG. 3 is an advantageous development of a server rack 1 of FIG. 2. In the server rack 1 of FIG. 3, a server 12 having a width B2, height H2 and depth T2 of specified dimensions is arranged by means of the four vertical support profiles 9.

In contrast to the server rack 1 of FIG. 2, the server rack 1 of FIG. 3 has a depth T1, which is dimensioned such that both region 5a and region 5b offer sufficient space for the reception of cablings of a plurality of servers 12 received in the server rack 1. Compared to region 5a of a server rack 1 of FIG. 2, region 5a has a significantly larger depth than server rack 1 of FIG. 3.

In addition, the server rack 1 of FIG. 3 comprises in each case one power supply manifold 6a and 6b as well as in each case one coolant manifold 7a and 7b in both region 5a at the front side 2 and region 5b at the rear side 3. The functions of the power supply manifolds 6a and 6b as well as of the coolant manifolds 7a and 7b correspond to the functionalities as described with respect to FIG. 1. Further explanations are not required at this point.

FIG. 4 shows a schematic illustration of a section through a server rack 1 according to the embodiment of FIG. 3 with further details. In particular, in addition to the features in FIG. 3, in FIG. 4 an interconnection or connection option of a server 12 is illustrated, the server arranged in the server rack 1.

Server 12 has, as described in FIG. 3, a width B2 and a height T2. Further, server 12 comprises a front side 13 and a rear side 14. A first voltage supply unit 17a is configured toward the front side 13 in the server 12. A second voltage supply unit 17b in the server 12 is configured toward the rear side 14 of the server 12. In this way, internal components of the server 12 can be supplied with one or multiple operating voltages both by the voltage supply unit 17a and by the voltage supply unit 17b, the operating voltage being generated from a supply voltage of an external power supply. To that end, the voltage supply unit 17a is connected to connections of the power supply manifold 6a of server rack 1 via electric supply connections 15a at the front side 13 of the server 12. In contrast thereto, the voltage supply unit 17b of server 12 is connected to connections of the power supply manifold 6b of the server rack 1 via electric supply connections 15b at the rear side 14 of the server 12.

For the generation of one or multiple coolant circuits through the server 12, server 12 is connected to the coolant manifold 7a in region 5a via coolant connections 16a and coolant lines 18a and 19a at the front side 13. In addition, server 12 is connected to the coolant manifold 7b in region 5b via coolant connections 16b and coolant lines 18b and 19b at the rear side 14. As a result, one or multiple coolant circuits are configured by the server 12, wherein the coolant circuits 18a and 18b belong to a cooling path and coolant lines 19a and 19b belong to a heat path of the coolant circuit. In this way, a coolant having a low temperature can be introduced in the server 12 via lines 18a and 18b, the coolant heating-up by the waste heat of the server 12 and being transformed out from the server 12 via heat path 19a and 19b. The waste heat will then be transported to a heat exchanger (not shown) in corresponding heat paths of the coolant manifolds 7a and 7b, so that the waste heat can be dissipated to the surroundings of the server rack 1.

However, it is to be noted that the server rack 1 of FIG. 4 has a depth T1, which is dimensioned such that the region 5a at the front side 2 of the server rack has a depth T3 and the region 5b at the rear side 3 of the server rack 1 has a depth T4. Depths T3 and T4 have approximately the same size. Further, the server 12 with its depth T2 occupies a region in the server rack 1 which is referred to with depth T5. The decisive factor is that the regions 5a and 5b each have a depth T3 and T4, respectively, which is dimensioned such that the illustrated cables of the server 12 can be received in the regions 5a and 5b with the power supply manifolds 6a and 6b and the coolant manifolds 7a and 7b.

By the advantageous configuration of a server rack 1 as well as of a server 12 of the explained type, a flexible cabling can be achieved within the server rack 1. The server rack 1 and the server 12 received therein have the synergetic effect that very high-performant servers 12 can be configured, the internal components of which can be cabled with corresponding components of the server rack 1 via connections both at the front side 13 and at the rear side 14 of the server 12. This achieves a very high power density of the server 12 and an improved cooling effect via coolant circuits that can be configured in a more flexible manner through the server 12.

### LIST OF REFERENCE NUMERALS

1 server rack
2 front side of the server rack
3 rear side of the server rack
4 reception region
5a, 5b additional regions
6a, 6b power supply manifold
7a, 7b coolant manifold
8 coolant lines
9 support profiles
10 cover openings
11 cover panel(s)
12 server
13 front side of the server
14 rear side of the server
15a, 15b supply connections of the server
16a, 16b coolant connections of the server
17a, 17b voltage supply unit
18a, 18b cooling path
19a, 19b heat path
B1, H1, R1 dimensions of the server rack
B2, H2, R2 dimensions of the server

1. A server rack, having a width, height and depth of specified dimensions, the server rack comprising:
a front side, a rear side and a reception region in the inside for receiving a plurality of servers, wherein
the depth of the server rack is dimensioned such that in addition to the reception region, regions are provided both toward the front side and toward the rear side so that cabling of a plurality of servers received in the server rack can be received in the additional regions both on the front side and on the rear side.

2. The server rack according to claim 1, wherein the additional regions each extend over the entire front side or the entire rear side, respectively.

3. The server rack according to claim 1, wherein a power supply manifold for connecting a plurality of servers received in the server rack to the power supply is set up in each of the additional regions at the front side and at the rear side.

4. The server rack according to claim 1, wherein a coolant manifold for connecting a plurality of servers received in the server for establishing one or multiple coolant circuits is set up in each of the additional regions at the front side and at the rear side.

5. The server rack according to claim 1, wherein the reception region in the interior of the server rack is accessible both from the front side and from the rear side.

6. A server for being received and operated in a server rack, comprising a housing with a width, height and depth of specified dimensions, a front side and a rear side as well as appropriate components for operating the server, which are received in the housing, the server comprising:
one or multiple connections for connecting the server to external operating components both at the front side and at the rear side.

7. The server according to claim 6, wherein the connections include one or multiple electric supply connections for connecting the server to an external power supply and/or one or multiple electric signal line connections for connecting the server to an external communication structure.

8. The server according to claim 7, wherein the server (12) has at least two voltage supply units for generating one or multiple operating voltages from one supply voltage of an external power supply, wherein a voltage supply unit is arranged in the region of the front side of the server and connected to the electric supply connections at the front side, and wherein a voltage supply unit is arranged in the region of the rear side of the server and connected to the electric supply connections at the rear side.

9. The server according to claim 6, wherein the connections include coolant connections for establishing one or multiple coolant circuits through the server.

10. A server rack assembly comprising:
a server rack; and
at least one server, wherein
the server rack includes a front side, a rear side and a reception region in the inside for receiving a plurality of servers,
the depth of the server rack is dimensioned such that in addition to the reception region, regions are provided both toward the front side and toward the rear side so that cabling of the at least one server in the server rack can be received in the additional regions both on the front side and on the rear side,
the at least one server including one or multiple connections for connecting the server to external operating components both at the front side and at the rear side.
